(19) United States
(12) Patent Application Publication
(10) Pub. No.: US 2009/0073659 A1
(43) Pub. Date: Mar. 19, 2009

(54) Heat sink structure for a power supply

(75) Inventor: Yun-Wen Peng, Tainan County (TW)

Correspondence Address: BACON & THOMAS, PLLC, 625 SLATERS LANE, FOURTH FLOOR, ALEXANDRIA, VA, 22314-1176, US

(73) Assignees: TOUCH ELECTRONIC CO. LTD., Tu Chen City (TW); YUAN YU INVESTMENT CO. LTD., Tainan City (TW)

(21) Appl. No.: 12/078,226

(22) Filed: Mar. 28, 2008

(30) Foreign Application Priority Data
Sep. 14, 2007 (TW) 096215583

(51) Int. Cl. H05K 7/20

(52) U.S. Cl. 361/709; 361/714

(57) ABSTRACT

A structure comprises a high thermally conductive case with a receiver space for a power module, a thermally conductive part being provided on the case to contact a heating component of the power module in the power supply to induct the heat by the heating component to the case and contact the exterior air through the outside surface of case to dissipate the heat; and a housing the inner surface of which directly contact and cover the outside of high thermally conductive case, a grid-formed structure being formed at most of the region of housing to prevent the heat from scalding the person who touches or takes the power supply. With the large heat dissipation area, the heat is transferred through the external air to increase the efficiency of heat dissipation, and further all power parts may operate in a lower temperature to increase the work efficiency of power supply.

### BACKGROUND OF THE INVENTION

1. Field of the Invention

This invention relates to a heat sink structure for a power supply and particularly to a heat sink structure that may promptly conduct out heat caused by an internal heating component and then quickly dissipate the heat by using air convection and prevent a human body from being scalded.

2. Description of Related Art

Along with electronic products that are continuously improved in the technology of manufacturing, all various devices are developed for a miniaturization scale without exception, such as a laptop PC, a LCD and the like as electronic products. For saving more space, a product designer even strives to refine a device body and peripherals thereof.

For example, for the demand of power, an electronic product is generally provided with a power supply for long-term and stable operation. With reference to FIG. 1, a conventional power supply provided for and supplying power to the electronic device for long-term operation comprises a power module 30 converting electric power, a plurality of air cooling fins 40 provided at the periphery of power module 30 to dissipate heat, and a housing receiving the power module 30 and the air cooling fins 40.

Such a power supply is generally covered by a plastic housing 50. When the power supply is used increasingly long, a heating component 31 provided in the internal power module 30 generates heat, and thus the air cooling fins 41 at the periphery of power module 30 suck and conduct it and then vent through the housing 50.

It is apparent that the housing 50 is not a good thermal conductor, and if match with an electronic device the power consumption of which is large, the housing 50 generates more heat. When the heat is vented, the whole power supply is made to stay in an undesirable status of high temperature. Thus, in another improved design, the housing 50 is provided with an air-cooling fan 51, and air vents 52 are formed on the surface of housing to compulsorily discharge the heat caused by the power module 30. However, those who are skilled in the art know that such a design is apparently complicated, gives a physical volume that is not easily reduced, make higher the manufacturing cost, and brings a defect of induction of the dust in the air into the housing and then pollution to the power module 30 due to the fans enhancing the ventilation, which is not what we expect.

Hereafter, being disclosed in Taiwan Patent No. 470873, namely U.S. Pat. No. 6,081,425, the air-cooling fin 40, the design of which is changed, covers the power module and is formed into a thermally conductive housing surrounding to prevent the external moisture and dust from entering the housing with airflow in the process of heat dissipation and then from polluting the circuit. However, in order to make the air contact the thermally conductive housing of the product, an air chamber is formed between the external plastic container and the internally covered thermally conductive housing for air circulation, and a ventilating opening is formed in the external container for air circulation, thereby an effect of air convection being enhanced. Thus, the formed air chamber relatively makes the physical volume of product large, which is disadvantageous to the product that is increasingly designed for miniaturization. Further, obviously, the effect of direct heat dissipation brought by the structure is not still desirable. Thus, in the embodiment, an air-cooling fan device is also provided to speed up the air convection, so the entire structure must be further improved.

Consequently, because of the technical defects of described above, the applicant keeps on carving unflaggingly through wholehearted experience and research to develop the present invention, which can effectively improve the defects described above.

### SUMMARY OF THE INVENTION

Accordingly, it is the object of this invention to mainly provide a heat sink structure for a power supply, which may directly contact exterior air and fast discharge the heat caused by an internal component in the power supply.

It is the other objective of this invention to provide a conventional heat sink structure of the power supply, which improves the undesirable heat dissipation of the conventional housing of power supply, the complicated structure caused by an additional fan, or the increasing physical volume caused by an additional air chamber provided inside.

The structure comprises a high thermally conductive case (that may be made of a metal or a high thermally conductive material), being defined that a receiver space is provided to receive a power module, in which a thermally conductive part is provided on the case to contact a heating component of the power module in the power supply to induct the heat caused by the heating component to the case and then directly contact the exterior air through the outside surface of case to dissipate the heat naturally; and a housing the inner surface of which directly contact and cover the outside of high thermally conductive case, in which a grid-formed structure that communicates inside and outside is formed at most of the region of housing to prevent the heat conducted to the heat sink surface of highly thermally conductive case from scalding the person who directly touches the case. With the large heat dissipation area of high thermally conductive case matching with the grid-formed structure, the heat may directly fast be transferred for convection through the external air to increase the efficiency of heat dissipation, and further all power parts may operate in the condition of lower temperature to increase the work efficiency of power supply.

In order to further elaborate the technical means and effects adopted for the object of this invention, refer to the detailed description according to this invention accompanied with drawings; it is believed that the object, features, and points of this invention will be apparent from the description; however, the accompanied drawings are provided for reference and illustration only and not limited to this invention.

### BRIEF DESCRIPTION OF THE DRAWINGS

FIG. 1 is a 3D exploded view of the structure of a conventional power supply;

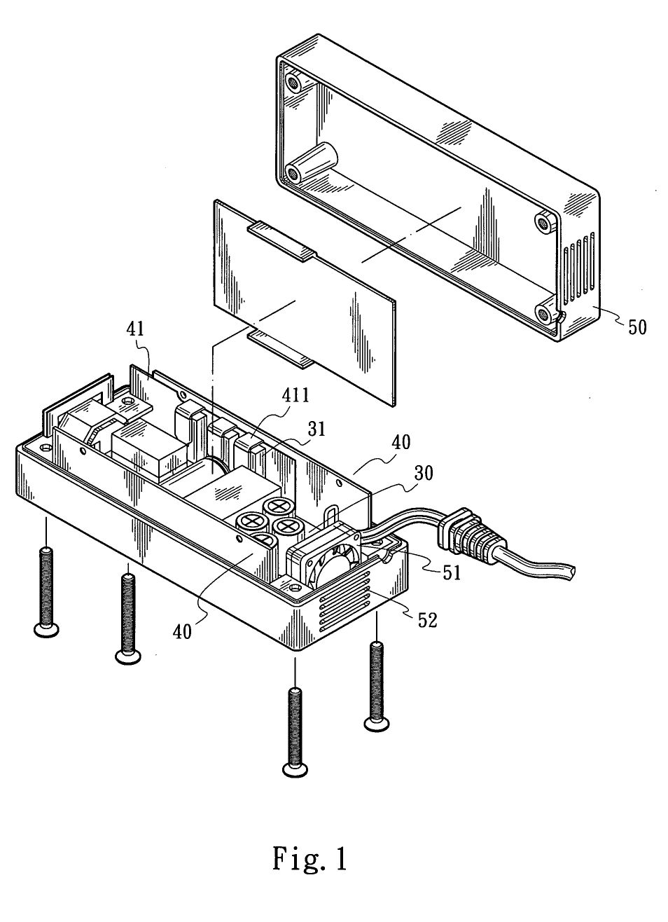

FIG. 2 is a 3D exploded view of the structure of a power supply according to this invention;

FIG. 3 is a 3D view of the assembly of parts of components of FIG. 2 into a structure;

FIG. 4 is a sectional view of a grid-formed structure; and

FIG. 5 is a schematic view illustrating an embodiment of this invention.

### DETAILED DESCRIPTION OF THE PREFERRED EMBODIMENTS

Now, the present invention will be described more specifically with reference to the following embodiments. It is to be noted that the following descriptions of preferred embodiments of this invention are presented herein for purpose of illustration and description only; it is not intended to be exhaustive or to be limited to the precise form disclosed.

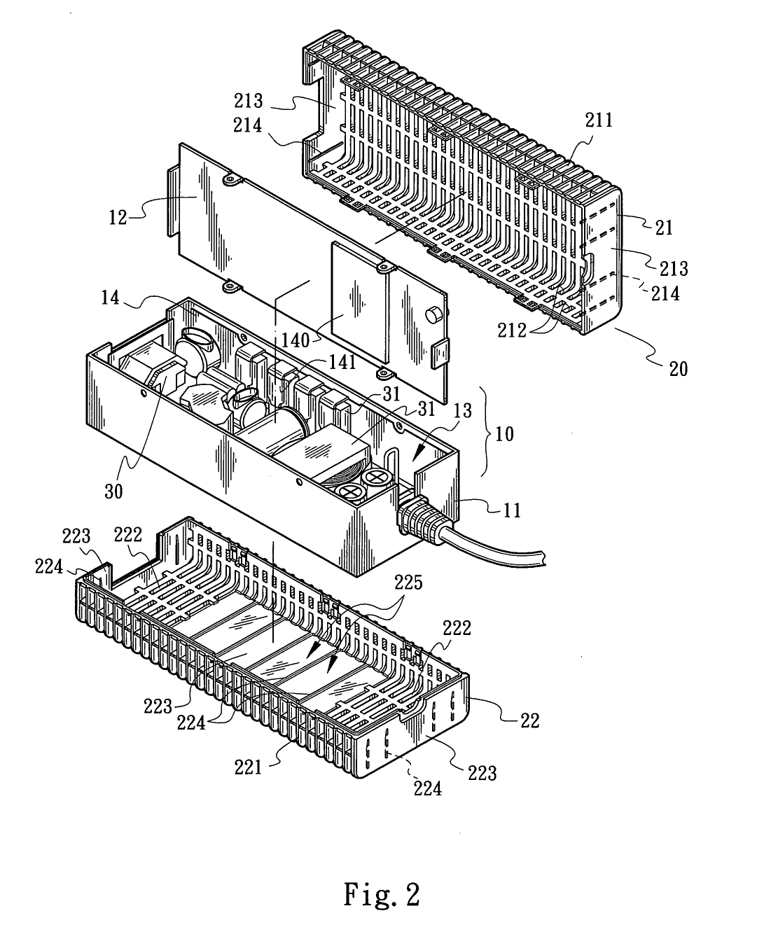

With reference to FIG. 2 illustrating a heat sink structure for a power supply in a preferred embodiment of this invention, the power supply comprises a high thermally conductive case 10 (that may be made of a metal or a non-metallic material), in which the case 10 is provided with a case 11 and a cover 12 that may be combined with the case 11, in which a receiver space 13 is formed to receive a power module 30. On the high thermally conductive case 10, thermally conductive parts 14 and 140 are provided and contact the heating component 31 of the power module 30. In the embodiment, the thermally conductive parts 14 and 140 are arranged between the heating component and the thermally conductive case 10, or in order to promote the function of thermally conductive parts 14 and 140, a stretching portion 141 is formed to contact the heating component 31 at different regions and then promptly conduct the heat caused by the heating component 31 to the high thermally conductive case 10 and dissipate it.

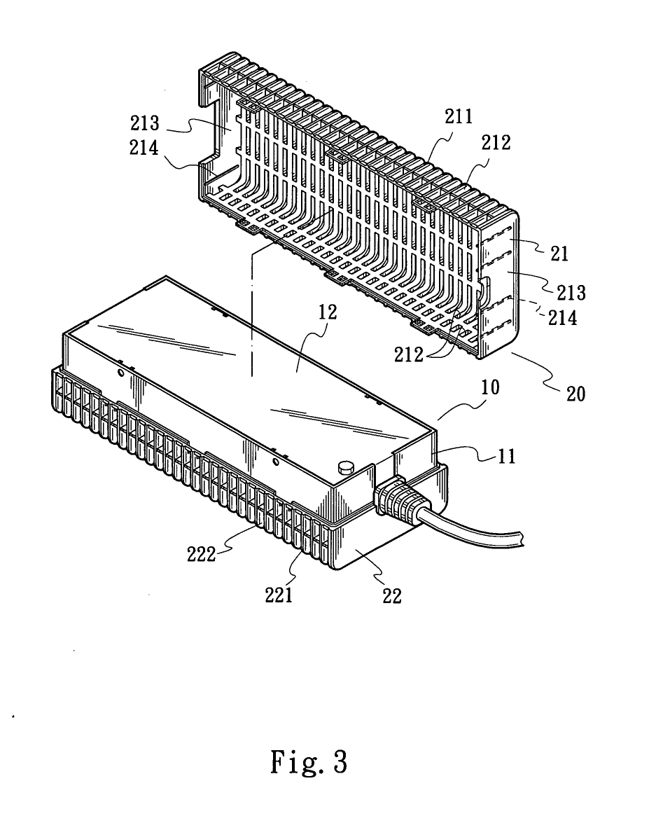

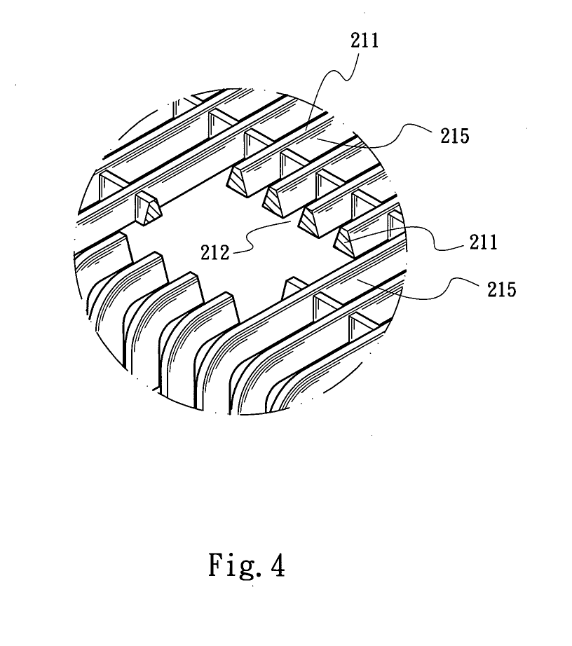

With reference to FIG. 3, a housing 20 is made of a low thermally conductive material and may be divided into upper and lower housing 21 and 22 and directly touch and cover the outside of thermally conductive case from its interior. Grid-formed frameworks 211 and 221 of grooves 212 and 222 the exterior and interior of which are communicate with each other are formed at most of the region (at least more than half the area) of the upper and lower housings 21 and 22. Thus, effective separation may be achieved through the housing 20, and the heat transferred to the heat sink surface of high thermally conductive case 10 may be prevented from scalding the person who touches or takes the power supply, besides, with high thermally conductive case 10 and the large-area grooves 212 and 222 of grid-formed frameworks 211 and 221, the heat may be directly fast transferred for convection through the external air. With reference to FIG. 4, the grid-formed frameworks 211 and 221 on the embodiment may be particularly formed with a awl-shaped section. It is clearly explained that a contact area where the grid-formed frameworks 211 and 221 face toward the high thermally conductive case 10 is larger and the other contact area where the grid-formed frameworks 211 and 221 face toward the exterior is smaller; thus, a larger inclined plane 215 may be further formed between the exterior and the interior and may bring the enhanced effect of heat dissipation for the housing 20.

Next, if a larger closed area (generally formed for an indicative labor) is required over the housing 20, at the closed areas 213 and 223, rib-formed frameworks 214 and 224 may be formed and face toward the high thermally conductive housing 10 so that when the housing 20 is combined with the high thermally conductive case 10, between the closed areas 213 and 223 and the high thermally conductive case 10, a convection space 225 communicating with the groove 222 is formed due to the separation of rib-formed frameworks 214 and 224 and works with the grooves 212 and 222 at the periphery of closed areas 213 and 223 to fast dissipate the heat caused by the thermally conductive case 10 in the closed areas 213 and 223.

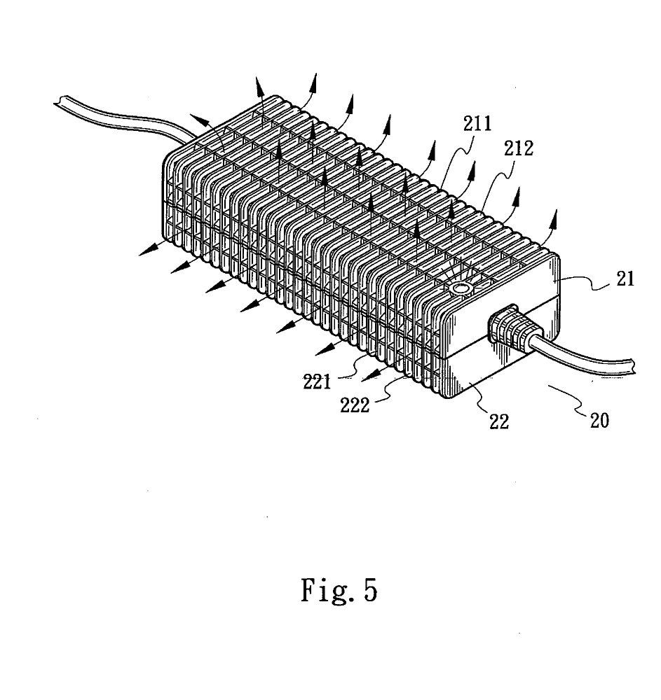

Refer to FIG. 5 illustrating a status of heat dissipation of the working power supply according to this invention. The high thermally conductive case 10 functions as a plastic case in a prior art that is used to receive the power module 30. Differently, compared with the conventional plastic case the heat of which is not easily dissipated, the high thermally conductive case 10 according to this invention is a good thermal conductor that may fast get rid of the heat caused inside; further, the large-area grid-formed frameworks 211 and 221 of the housing covering the high thermally conductive case 10 may bring the high efficiency of external air convection for the high thermally conductive case 10 the physical volume of which does not increase. The awl-shaped sections of the grid-formed frameworks 211 and 221 may further bring a preferable effect of heat dissipation for the housing 20, which prevents the user from touching the heat when taking the power supply or touching the power supply by accident and prevents the heat from causing an article of low ignition point to be on fire. The type of power supply is generally placed on the ground or at an unattractive site, so some articles are carelessly made to fall on the power supply and then dangerous overheating is caused.

Typically, the heat sink structure for the power supply according to this invention improves the defect of undesirable heat sink of the heat sink structure for the conventional power supply, and the defect of complicated heat sink structure. With the high thermally conductive case 10 made of the high thermally conductive material that is used to raise the efficiency of heat dissipation and with the housing 20 provided with the grid-formed frameworks 211 and 221 that are formed for heat insulation and dissipation, the conventional structure further provided with the fan may be improved.

To sum up, compared with the conventional structure, the heat sink structure for the power supply according to this invention is obviously better in the efficiency of heat dissipation so that the power supply may be further miniaturized. Thus, the portability and competition ability of product may increase so that the structure according to this invention is available in the industry and the efficiency of heat dissipation is greatly advanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A heat sink structure for a power supply, comprising a high thermally conductive case, being provided with a receiver space to receive a power module, in which a thermally conductive part is provided on the case to contact a power component of the power module in the power supply to induct the heat caused by the heating component onto the case and then dissipate out the heat; and a housing made of a low thermally conductive material, the inner surface of which contacts and covers the outside of high thermally conductive case, in which a grid-formed structure that communicates inside and outside is formed at most of the region of housing.

2. The heat sink structure for the power supply according to claim 1, wherein the thermally conductive part is arranged between the heating component and the high thermally conductive case and is provided with a stretching portion getting in touch with the heating component.

3. The heat sink structure for the power supply according to claim 1, wherein the high thermal conductive case is made of a metal.

4. The heat sink structure for the power supply according to claim 1, wherein a contact area where the grid-formed frameworks face toward the high thermally conductive case is larger and the other contact area where the grid-formed frameworks face toward the exterior is smaller, an inclined plane being formed.

5. The heat sink structure for the power supply according to claim 2, wherein a contact area where the grid-formed frameworks face toward the high thermally conductive case is larger and the other contact area where the grid-formed frameworks face toward the exterior is smaller, an inclined plane being formed.

6. The heat sink structure for the power supply according to claim 1, wherein at least upper and lower shells are structured into the housing.

7. The heat sink structure for the power supply according to claim 2, wherein at least upper and lower shells are structured into the housing.

8. The heat sink structure for the power supply according to claim 4, wherein at least the upper and lower shells are structured into the housing.

9. The heat sink structure for the power supply according to claim 5, wherein at least the upper and lower shells are structured into the housing.

10. The heat sink structure for the power supply according to claim 1, wherein at least a case and a cover that are correspondingly assembled with each other are structured into the high thermally conductive case.

11. The heat sink structure for the power supply according to claim 2, wherein at least a case and a cover that are correspondingly assembled with each other are structured into the high thermally conductive case.

12. The heat sink structure for the power supply according to claim 4, wherein at least the case and the cover that are correspondingly assembled with each other are structured into the high thermally conductive case.

13. The heat sink structure for the power supply according to claim 5, wherein at least the case and the cover that are correspondingly assembled with each other are structured into the high thermally conductive case.

14. The heat sink structure for the power supply according to claim 6, wherein at least the case and the cover that are correspondingly assembled with each other are structured into the high thermally conductive case.

15. The heat sink structure for the power supply according to claim 7, wherein at least the case and the cover that are correspondingly assembled with each other are structured into the high thermally conductive case.

16. The heat sink structure for the power supply according to claim 1, wherein a closed area is formed over the housing on which a rib-formed framework is formed toward the interior for separation of the interior of housing from the high thermally conductive case.

17. The heat sink structure for the power supply according to claim 2, wherein a closed area is formed over the housing on which a rib-formed framework is formed toward the interior for separation of the interior of housing from the high thermally conductive case.

18. The heat sink structure for the power supply according to claim 4, wherein the closed area is formed over the housing on which the rib-formed framework is formed toward the interior for separation of the interior of housing from the high thermally conductive case.

19. The heat sink structure for the power supply according to claim 5, wherein the closed area is formed over the housing on which the rib-formed framework is formed toward the interior for separation of the interior of housing from the high thermally conductive case.

20. The heat sink structure for the power supply according to claim 6, wherein the closed area is formed over the housing on which the rib-formed framework is formed toward the interior for separation of the interior of housing from the high thermally conductive case.

21. The heat sink structure for the power supply according to claim 7, wherein the closed area is formed over the housing on which the rib-formed framework is formed toward the interior for separation of the interior of housing from the high thermally conductive case.

22. The heat sink structure for the power supply according to claim 8, wherein the closed area is formed over the housing on which the rib-formed framework is formed toward the interior for separation of the interior of housing from the high thermally conductive case.

23. The heat sink structure for the power supply according to claim 9, wherein the closed area is formed over the housing on which the rib-formed framework is formed toward the interior for separation of the interior of housing from the high thermally conductive case.

24. The heat sink structure for the power supply according to claim 10, wherein the closed area is formed over the housing on which the rib-formed framework is formed toward the interior for separation of the interior of housing from the high thermally conductive case.

25. The heat sink structure for the power supply according to claim 11, wherein the closed area is formed over the housing on which the rib-formed framework is formed toward the interior for separation of the interior of housing from the high thermally conductive case.

26. The heat sink structure for the power supply according to claim 12, wherein the closed area is formed over the housing on which the rib-formed framework is formed toward the interior for separation of the interior of housing from the high thermally conductive case.
